(19) United States
(12) Patent Application Publication
(10) Pub. No.: US 2026/0259248 A1
(43) Pub. Date: Sep. 3, 2026

(54) MULTI-AIR-GAP MAGNETORESISTANCE CURRENT SENSOR FOR ALTERNATING CURRENT AND DIRECT CURRENT, AND CURRENT MEASURING METHOD

(71) Applicants: China Electric Power Research Institute, Beijing (CN); China Electric Power Research Institute Wuhan Branch, Wuhan, Hubei (CN); State Grid Corporation of China, Beijing (CN)

(72) Inventors: Feng ZHOU, Wuhan (CN); Jicheng YU, Wuhan (CN); Siyuan LIANG, Wuhan (CN); Changxi YUE, Wuhan (CN); Min LEI, Wuhan (CN); Xiaodong YIN, Wuhan (CN); Dengyun LU, Wuhan (CN); Zili XU, Wuhan (CN); Kui XIONG, Wuhan (CN); Kai ZHU, Wuhan (CN); Jiaxin LI, Wuhan (CN)

(21) Appl. No.: 18/717,473

(22) PCT Filed: Aug. 30, 2023
(86) PCT No.: PCT/CN2023/115940

§ 371 Date: Jun. 7, 2024

(30) Foreign Application Priority Data
Jun. 26, 2023 (CN) 202310762174.0

(51) Int. Cl. G01R 15/20; G01R 19/00

(52) U.S. Cl. CPC G01R 15/205; G01R 19/0023

(57) ABSTRACT

A multi-air-gap magnetoresistance current sensor for alternating current-direct current and a current measurement method are provided, and the multi-air-gap magnetoresistance current sensor for alternating current-direct current includes: a magnetoelectric conversion unit, configured to obtain a magnetic field signal of a target current-carrying wire with to-be-measured current, convert the magnetic field signal into an electric signal, and output the electric signal to a signal processing unit, the magnetoelectric conversion unit adopts a multi-air-gap multi-band closed-loop iron core type structure; a signal processing unit, configured to amplify the electric signal and output the electric signal to a feedback compensation unit; and the feedback compensation unit, configured to adjust a feedback current according to the amplified voltage signal to enable the new magnetoresistance elements to operate at zero magnetic flux, measure a feedback current value, and obtain and output a value of to-be-measured current according to the feedback current value.

### CROSS-REFERENCE TO RELATED APPLICATIONS

This application claims the benefit of the Chinese Patent Application No. 202310762174.0, filed to the China National Intellectual Property Administration on Jun. 26, 2023, and entitled “MULTI-AIR-GAP MAGNETORESISTANCE CURRENT SENSOR FOR ALTERNATING CURRENT AND DIRECT CURRENT, AND CURRENT MEASURING METHOD”, which is incorporated by reference herein in its entirety.

### TECHNICAL FIELD

The disclosure relates to the technical field of electrical measurement, in particular to a multi-air-gap magnetoresistance current sensor for alternating current-direct current and a method for measuring a current.

### BACKGROUND

The new power system has a high proportion of renewable energy and a high proportion of power electronic equipment. High-voltage and high-current contain complex components such as power frequency, harmonics and direct current, presenting characteristics of wide dynamic, strong random and strong time-varying. However, the existing mainstream current sensors are difficult to meet the measurement requirements of current signals in complex environments in terms of characteristics of accuracy and wide dynamic simultaneously. The mainstream current measurement device on the neutral line of the high-voltage direct current transmission system is a zero-flux type direct-current current transformer, which is difficult to measure high-frequency harmonics and has a poor insulation performance. Hall current sensor is often used for photovoltaic power station connected to power grid, which has limited accuracy and is susceptible to environmental disturbances such as temperature. In recent years, new magnetoresistance sensing technology with high sensitivity has been gradually applied, but there are some problems such as poor anti-interference ability, conductor eccentricity error, frequency response consistency, etc. Moreover, due to the influence of core magnetic hysteresis effect, the linear range and accuracy are limited.

### SUMMARY

In view of this, a multi-air-gap magnetoresistance current sensor for alternating current-direct current and a method for measuring a current are proposed in the disclosure, which aims to solve the problems of poor anti-interference ability, conductor eccentricity error, frequency response consistency, the influence of magnetic hysteresis effect of iron core and so on of the existing sensing technology.

In the first aspect, the embodiment of the disclosure provides a multi-air-gap magnetoresistance current sensor for alternating current-direct current, including a magnetoelectric conversion unit, a signal processing unit and a feedback compensation unit. The magnetoelectric conversion unit is configured to: obtain a magnetic field signal of a target current-carrying wire with a to-be-measured current; and convert the magnetic field signal into an electric signal and output the electric signal to the signal processing unit. The magnetoelectric conversion unit includes an iron core and N new magnetoresistance elements connected in parallel, N air-gap openings are symmetrically arranged on the iron core, and the N new magnetoresistance elements are respectively located at centers of the N air-gap openings, N≥3 and N is a positive integer. The signal processing unit is configured to: amplify the electric signal output by the magnetoelectric conversion unit, and output the amplified signal to the feedback compensation unit. The feedback compensation unit is configured to: adjust a feedback current based on the amplified voltage signal output by the signal processing unit to enable the new magnetoresistance elements to operate at zero magnetic flux; measure a value of the feedback current; and obtain a value of the to-be-measured current based on the value of the feedback current, and output the value of the to-be-measured current.

Furthermore, the iron core is a circular magnetic gathering ring and is uniformly wound with a feedback winding, and the magnetoelectric conversion unit further includes a power supply circuit which is respectively connected to the N new magnetoresistance elements for power supply. When the target current-carrying wire with the to-be-measured current is placed at a center of the iron core, the N new magnetoresistance elements are used for obtaining the magnetic field signal of the target current-carrying wire with the to-be-measured current, converting the magnetic field signal into the electric signal and outputting the electric signal to the signal processing unit.

Furthermore, the operation that the N new magnetoresistance elements are used for obtaining the magnetic field signal of the target current-carrying wire with the to-be-measured current, converting the magnetic field signal into the electric signal and outputting the electric signal to the signal processing unit, includes obtaining an input voltage Vᵢ of each of the new magnetoresistance elements by the following formula:

$${V}_{i} = {K}_{i} {I}_{i} ( {B}_{i n} - {B}_{c} ) ;$$

where Kᵢ is a sensitivity of i-th new magnetoresistance element, Iᵢ is a control current of the i-th new magnetoresistance element, Bᵢₙ is a primary original magnetic field, and B_{c} is a compensation magnetic field generated by the feedback current. Based on the input voltage of each new magnetoresistance element, a synthesis is performed and a combined voltage of the N new magnetoresistance elements is obtained according to an equivalent circuit of parallel capacitors, and the combined voltage is output to the signal processing unit.

Furthermore, the new magnetoresistance element is a tunneling magnetoresistance element.

Furthermore, the signal processing unit includes a detecting circuit, an interference suppression circuit, and a multi-band feedback circuit. The detecting circuit includes an instrumentation amplifier with three operational amplifiers. The detecting circuit is configured to amplify the voltage signal output by the magnetoelectric conversion unit, and output the amplified voltage signal to the feedback compensation unit. The interference suppression circuit is used for an element performance error correction circuit and a filtering circuit, the element performance error correction circuit is configured to generate a regulating current based on the voltage signal output by the magnetoelectric conversion unit, and the filtering circuit is configured to filter high-frequency magnetic field signals coupled by the new magnetoresistance elements to ensure a low-pass characteristic. The multi-band feedback circuit includes multiple dynamic output feedback control circuits for ensuring that the transmission characteristics of different frequencies are consistent, and each of the multiple dynamic output feedback control circuits has a limited frequency band.

Furthermore, the feedback compensation unit includes the feedback winding, a driving circuit and an output circuit. The feedback winding is uniformly wound on the iron core, and configured to pass the feedback current. The driving circuit is configured to adjust the feedback current output to the feedback winding based on the amplified voltage signal output by the signal processing unit, to enable a compensation magnetic field equal in size and opposite in direction to a primary magnetic field. The output circuit is configured to: measure the value of the feedback current, obtain the value of the to-be-measured current based on the value of the feedback current, and output the value of the to-be-measured current.

Furthermore, the operation of obtaining the value of the to-be-measured current based on the value of the feedback current includes dividing the value of the feedback current by a ratio of coil turns to obtain the value of the to-be-measured current.

Furthermore, the multi-air-gap magnetoresistance current sensor for alternating current-direct current further includes a ring housing for carrying the iron core wound with the feedback winding and the N new magnetoresistance elements connected in parallel.

Furthermore, the ring housing is voltage insulated by using an insulating layer.

In the second aspect, the embodiment of the disclosure provides a method for measuring a current, including: using the multi-air-gap magnetoresistance current sensor for alternating current-direct current provided by the above embodiments to measure a to-be-measured current in a target current-carrying wire, to obtain a value of the to-be-measured current and output the value of the to-be-measured current. The target current-carrying wire is at a center of an iron core of the multi-air-gap magnetoresistance current sensor for alternating current-direct current.

The multi-air-gap magnetoresistance current sensor for alternating current-direct current and the method for measuring a current are provided in the embodiments of the disclosure. The multi-air-gap magnetoresistance current sensor for alternating current-direct current adopts a multi-air-gap multi-band closed-loop iron core type structure, thereby improving the measurement performance of the current sensor, solving the problem of high accuracy and wide frequency domain consideration of current measurement for alternating current-direct current, providing technical guidance for the development and application of high-voltage and high-current measurement equipment, and promoting the technology upgrade of high-voltage and high-current measurement equipment.

### BRIEF DESCRIPTION OF THE DRAWINGS

FIG. 1 illustrates a schematic structural diagram of a multi-air-gap magnetoresistance current sensor for alternating current-direct current according to an embodiment of the disclosure; and

FIG. 2 illustrates a schematic structural diagram of a housing of a multi-air-gap magnetoresistance current sensor for alternating current-direct current according to an embodiment of the disclosure.

### DETAILED DESCRIPTION

Exemplary implementations of the disclosure are now described with reference to the accompanying drawings. However, the disclosure may be implemented in many different forms and is not limited to the embodiments described herein, and the embodiments are provided to thoroughly and completely disclose the disclosure and to fully convey the scope of the disclosure to those skilled in the technical field. The terms used in the exemplary implementations representing in the drawings is not a limitation to the disclosure. In the drawings, the same units/elements are indicated by the same reference numerals.

Unless otherwise stated, the terms (including technical terms) used herein have a common understanding to those skilled in the technical field. In addition, it is understood that terms defined in commonly used dictionaries should be understood to have meanings consistent with the context of their relevant fields, and should not be understood as an idealized or overly formal sense.

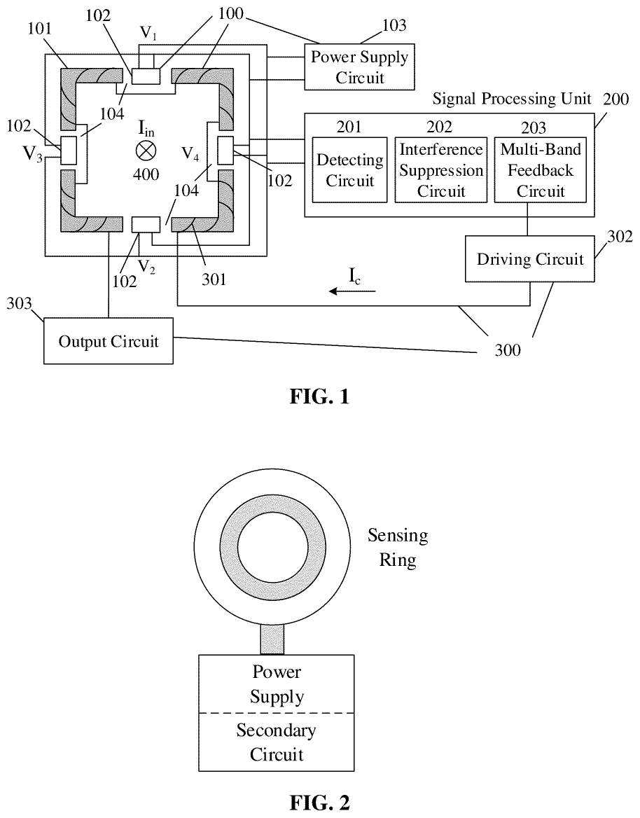

FIG. 1 illustrates a schematic structural diagram of a multi-air-gap magnetoresistance current sensor for alternating current-direct current according to an embodiment of the disclosure.

As illustrated in FIG. 1, the multi-air-gap magnetoresistance current sensor for alternating current-direct current includes: a magnetoelectric conversion unit 100, a signal processing unit 200 and a feedback compensation unit 300.

The magnetoelectric conversion unit 100 is configured to: obtain a magnetic field signal of a target current-carrying wire 400 with a to-be-measured current; and convert the magnetic field signal into an electric signal and outputting the electric signal to the signal processing unit 200. The magnetoelectric conversion unit 100 includes an iron core 101 and N new magnetoresistance elements 102 connected in parallel, N air-gap openings 104 are symmetrically arranged on the iron core 101, and the N new magnetoresistance elements 102 are respectively located at centers of the N air-gap openings 104, N≥3 and N is a positive integer.

Furthermore, the iron core 101 is a circular magnetic gathering ring and is uniformly wound with a feedback winding 301, and the magnetoelectric conversion unit further includes a power supply circuit 103 which is respectively connected to the N new magnetoresistance elements 102 for power supply.

When the target current-carrying wire 400 with the to-be-measured current is placed at a center of the iron core 101, the N new magnetoresistance elements 102 are used for obtaining the magnetic field signal of the target current-carrying wire 400 with the to-be-measured current, converting the magnetic field signal into the electric signal and outputting the electric signal to the signal processing unit 200.

The above embodiment adopts a multi-air-gap multi-band closed-loop iron core type structure, that is, the high interference sensitivity of the ring array current sensor is avoided through the magnetic gathering effect of the iron core, the wire eccentricity and non-uniform winding error of the single-air-gap iron core type structure are avoided through the multi-air-gap, and the hysteresis effect of the iron core is avoided through the zero magnetic flux closed-loop structure.

Furthermore, the operation that the N new magnetoresistance elements are used for obtaining the magnetic field signal of the target current-carrying wire with the to-be-measured current, converting the magnetic field signal into the electric signal and outputting the electric signal to the signal processing unit, includes that:
an input voltage Vᵢ of each new magnetoresistance element is obtained by the following formula (1):

$${V}_{i} = {K}_{i} {I}_{i} ( {B}_{i n} - {B}_{c} ) \qquad ( 1 )$$

where Kᵢ is a sensitivity of i-th new magnetoresistance element, Iᵢ is a control current of the i-th new magnetoresistance element, Bᵢₙ is a primary original magnetic field, and B_{c} is a compensation magnetic field generated by the feedback current; and
based on the input voltage of each new magnetoresistance element, a synthesis is performed and a combined voltage of the N new magnetoresistance elements is obtained according to an equivalent circuit of parallel capacitors, and the combined voltage is outputted to the signal processing unit.

Furthermore, the new magnetoresistance element is a tunneling magnetoresistance (TMR) element.

The above embodiment adopts new magnetoresistance element such as TMR and has the advantages of high sensitivity, wide frequency response range and the like.

The signal processing unit 200 is configured to: amplify the electric signal output by the magnetoelectric conversion unit 100, and output the amplified signal to the feedback compensation unit 300.

Furthermore, the signal processing unit 200 includes: a detecting circuit 201, an interference suppression circuit 202 and a multi-band feedback circuit 203.

The detection circuit 201 includes an instrumentation amplifier with three operational amplifiers. The detecting circuit is configured to amplify the voltage signal output by the magnetoelectric conversion unit, and outputting the amplified voltage signal to the feedback compensation unit.

The interference suppression circuit 202 is used for an element performance error correction circuit and a filtering circuit. The element performance error correction circuit is configured to generate a regulating current based on the voltage signal output by the magnetoelectric conversion unit. The filtering circuit is configured to filter high-frequency magnetic field signals coupled by the new magnetoresistance elements to ensure a low-pass characteristic.

The multi-band feedback circuit 203 includes multiple dynamic output feedback control circuits for ensuring that the transmission characteristics of different frequencies are consistent, and each of the multiple dynamic output feedback control circuits has a limited frequency band.

The detection circuit is configured to amplify the weak output voltage with small amplitude of TMR element for operations and filtering. The detection circuit is mainly composed of an instrumentation amplifier with three operational amplifiers, and its REF pin is grounded to keep a very low source impedance. In the detection circuit, a zeroing circuit is designed, in which a precision adjustable resistor is connected in series between two equivalent resistors, and a precision operational amplifier is used as a voltage follower for buffering. The positive input terminal of the precision operational amplifier is connected to the middle pin of the precision adjustable resistor, and its output serves as an output of a zeroing voltage.

The interference suppression circuit includes the element performance error correction circuit and the filtering circuit. The element performance error correction and compensation method based on a signal injection method is used through the decomposition unit according to the distinctive waveform characteristics, to identify the excitation signal from the current detected by TMR element, which is used to calculate the overall gain of the measuring loop of the magnetosensitive sensor, determine the change of the measurement characteristics of the magnetosensitive resistor chip, and generate a regulating current. The filter circuit is configured to filter the possibly coupled high-frequency magnetic field signal to ensure a low-pass characteristics. The filter circuit adopts a second-order Butterworth low-pass filter built based on a precision operational amplifier.

The multi-band feedback circuit is designed according to the multi-band feedback mechanism, to determine the difference in the responses, in the sensor circuit, of current signals in different frequency ranges from low frequency to high frequency; and multiple dynamic output feedback control circuits (each dynamic output feedback control circuit having a limited frequency band) are designed for different frequency domains for ensuring that the transmission characteristics of different frequencies are consistent.

The above embodiment adopts a multi-physical field interference suppression method, the zero drift is corrected by a detection circuit with a zero drift correction, the element performance error is corrected by the element error correction and compensation circuit module based on a signal injection method, and the possibly coupled electromagnetic field interference signals are filtered by an electromagnetic field interference filter. By adopting the multi-band feedback mechanism, the consistency of the transmission characteristics of different frequencies is ensured.

The feedback compensation unit 300 is configured to: adjust a feedback current based on the amplified voltage signal output by the signal processing unit 200 to enable the new magnetoresistance elements to operate at zero magnetic flux; measure a value of the feedback current; and obtain a value of the to-be-measured current based on the value of the feedback current, and output the value of the to-be-measured current.

Furthermore, the feedback compensation unit 300 includes: a feedback winding 301, a driving circuit 302 and an output circuit 303.

The feedback winding 301 is uniformly wound on the iron core, and configured to pass the feedback current.

The driving circuit 302 is configured to adjust the feedback current output to the feedback winding based on the amplified voltage signal output by the signal processing unit, to enable a compensation magnetic field equal in size and opposite in direction to a primary magnetic field.

The output circuit 303 is configured to: measure the value of the feedback current, obtain the value of the to-be-measured current based on the value of the feedback current, and output the value of the to-be-measured current.

Furthermore, the operation of obtaining the value of the to-be-measured current based on the value of the feedback current includes:
dividing the value of the feedback current by a ratio of coil turns to obtain the value of the to-be-measured current.

The amplified output voltage drives the push-pull transistor, to adjust the feedback current I_{c} output to the compensation coil wound on the iron core, to enable the compensation magnetic field equal in size and opposite in direction to the primary magnetic field, allowing the TMR element to always operate near the zero magnetic flux; in this moment, the ratio of I_{c} to the primary current Iᵢₙ is the ratio of coil turns. Then the voltage on the feedback current I_{c} is measured by measuring the resistance, to obtain a result of measuring Iᵢₙ. As a result, the actual magnetic field on the sensor is the difference between the external magnetic field and the feedback magnetic field, and the sensor actually operates within a very small magnetic field range.

Furthermore, the multi-air-gap magnetoresistance current sensor for alternating current-direct current further includes a ring housing for carrying the iron core wound with the feedback winding and the N new magnetoresistance elements connected in parallel. The ring housing is voltage insulated by using a special processed ring insulating layer.

Furthermore, the ring housing is voltage insulated by using an insulating layer.

FIG. 2 illustrates a schematic structural diagram of a housing of a multi-air-gap magnetoresistance current sensor for alternating current-direct current according to an embodiment of the disclosure. As illustrated in FIG. 2, the ring housing and the iron core wound with the feedback winding and the N new magnetoresistance elements connected in parallel carried inside the ring housing can form a sensing ring. The voltage insulated is realized by using a special processed ring insulation layer inside the sensing ring, and the power supply and the secondary circuit realize current sensing on the low-voltage side.

The ring housing is adopted to ensure the insulation performance of the sensor.

The above embodiment provides an multi-air-gap magnetoresistance current sensor for alternating current-direct current, which adopts a multi-air-gap multi-band closed-loop iron core type structure, thereby improving the measurement performance of the current sensor, solving the problem of high accuracy and wide frequency domain consideration of current measurement for alternating current-direct current, providing technical guidance for the development and application of high-voltage and high-current measurement equipment, and promoting the technology upgrade of high-voltage and high-current measurement equipment.

The embodiment of the disclosure also provides a method for measuring a current, including: using the multi-air-gap magnetoresistance current sensor for alternating current-direct current provided by the above embodiments to measure a to-be-measured current in a target current-carrying wire, to obtain a value of the to-be-measured current and output the value of the to-be-measured current. The target current-carrying wire is at a center of an iron core of the multi-air-gap magnetoresistance current sensor for alternating current-direct current.

The multi-air-gap magnetoresistance current sensor for alternating current-direct current and the method for measuring a current are designed in embodiments of the disclosure, the high interference sensitivity of the ring array current sensor is avoided, the error influence such as wire eccentricity and external interference are avoided and the hysteresis effect of the iron core is avoided, thereby solving the problem of high accuracy and wide frequency domain consideration in direct current measurement with high-voltage and high-current.

The multi-air-gap magnetoresistance current sensor for alternating current-direct current mainly includes: a magnetoelectric conversion section, a signal processing section and a feedback compensation section.

The magnetoelectric conversion section consists of an iron core, 4 TMR elements and a power supply circuit. Among them, the iron core is circular and the cross section is square, which is made of iron-based nanocrystalline alloy or permalloy material. The iron core is uniformly wound with a feedback winding, and 4 air-gap openings are symmetrically arranged on the iron core.

The 4 TMR elements of the magnetoelectric conversion section are respectively located at centers of the 4 air-gap openings of the iron core. The formula for calculating the input voltage of each TMR element can refer to the aforementioned formula (1) when the iron core is placed around the current-carrying wire with the to-be-measured current I_in.

Because the current-carrying wire may not locate at the center of the iron core, the primary magnetic fields caused by the primary current at the air-gaps are different. The total magnetic field formed by the primary magnetic field and the feedback magnetic field in the air-gap at the i-th TMR element is represented as Bᵢ. After connecting the circuits in parallel, synthesizing and obtaining the combined output voltages of the 4 TMR elements according to an equivalent circuit of parallel capacitors are as follows:

$${V}_{s} = {{\sum }^{4}}_{i = 1} {K}_{i} {I}_{i} {B}_{i} = {{\sum }^{4}}_{i = 1} {V}_{i} \qquad ( 2 )$$

The combined output voltage of the TMR elements is input into the signal processing section.

In the power supply circuit of the magnetoelectric conversion section, a Low Dropout Regulator (LDO) chip is selected as the power supply of the TMR elements, using a 2.2 μF small ceramic output capacitor to maintain a stable of the fixed output voltage, which supplies power to four TMR elements. The temperature drift error correction and compensation circuit based on a thermistor is designed, and a same-phase proportional amplifier circuit is built through the thermistor with negative temperature coefficient, which adjusts the supply voltage of TMR sensing chip when the temperature changes.

The signal processing section consists of the detection circuit, the interference suppression circuit and the multi-band feedback circuit. The detection circuit is configured to amplify the weak output voltage with small amplitude of TMR element for operations and filtering. The detection circuit is mainly composed of an instrumentation amplifier with three operational amplifiers, and its REF pin is grounded to keep a very low source impedance. In the detection circuit, a zeroing circuit is designed, in which a precision adjustable resistor is connected in series between two equivalent resistors, and a precision operational amplifier is used as a voltage follower for buffering. The positive input terminal of the precision operational amplifier is connected to the middle pin of the precision adjustable resistor, and its output serves as an output of a zeroing voltage.

The interference suppression circuit of the signal processing section includes the element performance error correction circuit and the filtering circuit. The element performance error correction and compensation method based on a signal injection method is used through the decomposition unit according to the distinctive waveform characteristics, to identify the excitation signal from the current detected by TMR element, which is used to calculate the overall gain of the measuring loop of the magnetosensitive sensor, determine the change of the measurement characteristics of the magnetosensitive resistor chip, and generate a regulating current. The filter circuit is configured to filter the possibly coupled high-frequency magnetic field signal to ensure a low-pass characteristic. The filter circuit adopts a second-order Butterworth low-pass filter built based on a precision operational amplifier.

The multi-band feedback circuit of the signal processing section is designed according to the multi-band feedback mechanism. According to the difference in the responses, in the sensor circuit, of current signals at different frequencies, multiple dynamic output feedback control circuits (each dynamic output feedback control circuit having a limited frequency band) are designed, the optimization goal of which is to ensure that the transmission characteristics of different frequencies from low frequency to high frequency signals are consistent.

The feedback compensation section consists of the driving circuit, the feedback winding and the output circuit. The amplified output voltage drives the push-pull transistor, and the transistor outputs the feedback current I_{c} to the compensation coil. During the period of not exceeding the measuring range, the magnetic field generated by the output current of the operational amplifier and transistor operating in the linear region is equal in size and opposite in direction to the measured magnetic field. The feedback winding receives the feedback current output by the transistor, the magnetic field may be generated by the feedback current, and represented as B_{c}:

$${B}_{c} = \frac{{μ}_{0} {N}_{2} {I}_{c}}{d} \qquad ( 3 )$$

where I_{c} is the feedback current, N₂ is the number of turns of the compensation coil. When the compensation magnetic field cancels out the original magnetic field to reach the zero magnetic flux, that is:

$$\frac{{μ}_{0}}{d} ( {N}_{2} {I}_{c} - {I}_{i n} ) = 0 \qquad ( 4 )$$

At this time, N₂I_{c}=Iᵢₙ is obtained, that is to say, the ratio of I_{c} to the primary current Iᵢₙ is the ratio of coil turns. Then the feedback current I_{c} is measured according to Ohm's law, the result of measuring Iᵢₙ, is obtained. As a result, the actual magnetic field on the sensor is the difference between the external magnetic field and the feedback magnetic field, and the sensor actually operates within a very small magnetic field range.

The design scheme of the external structure of the current sensor is as follows: according to the above high-voltage direct current quantum tunneling magnetoresistance current sensing method, the magnetoelectric conversion section is designed as a sensing ring. The voltage insulated is realized by using a special processed ring insulation layer inside the sensing ring, and the power supply and the secondary circuit realize current sensing on the low voltage side.

The multi-air-gap magnetoresistance current sensor for alternating current-direct current and the method for measuring a current are designed in the disclosure, including the following technical solutions:
(1) multi-air-gap multi-band closed-loop iron core type structure: the high interference sensitivity of the ring array current sensor is avoided through the magnetic gathering effect of the iron core, the wire eccentricity and non-uniform winding error of the single-air-gap iron core type structure are avoided through the multi-air-gap, and the hysteresis effect of the iron core is avoided through the zero magnetic flux closed-loop structure;
(2) multi-physical field interference suppression method: the temperature drift error is corrected by a power supply with the temperature drift error correction and compensation circuit, the zero drift is corrected by a detection circuit with a zero drift correction, the element performance error is corrected by the element error correction and compensation circuit module based on a signal injection method, and the possibly coupled electromagnetic field interference signals are filtered by an electromagnetic field interference filter;
(3) multi-band feedback mechanism: the consistency of the transmission characteristics of different frequencies is ensured;
(4) external structural design with ring insulation layer: the insulation performance of the sensor is ensured.

Through the above technical solutions, the measurement performance of quantum tunneling magnetoresistance current sensor is improved, the problem of high accuracy and wide frequency domain consideration of current measurement for alternating current-direct current is solved, the technical guidance is provided for the development and application of high-voltage and high-current measurement equipment, and the technology upgrade of high-voltage and high-current measurement equipment is promoted.

The disclosure provides a multi-air-gap magnetoresistance current sensor for alternating current-direct current, mainly including a magnetoelectric conversion section, a signal processing section and a feedback compensation section.

The magnetoelectric conversion section consists of an iron core, a power supply circuit and four TMR elements. Among them, the iron core is circular and the cross section is square, which is made of iron-based nanocrystalline alloy or permalloy material. The iron core is uniformly wound with a feedback winding, and four air-gap openings are symmetrically arranged on the iron core. The four TMR elements are respectively located at centers of the four air-gaps of the iron core. The combined output voltage of the TMR elements is input into the signal processing section.

In the power supply circuit of the magnetoelectric conversion section, an LDO chip is selected as the power supply of the TMR elements, using 2.2 μF small ceramic output capacitor to maintain a stable of the fixed output voltage, which supplies power to four TMR elements. The temperature drift error correction and compensation circuit based on a thermistor is designed, and a same-phase proportional amplifier circuit is built through the thermistor with negative temperature coefficient, which adjusts the supply voltage of TMR sensing chip when the temperature changes.

The signal processing section consists of the detection circuit, the interference suppression circuit and the multi-band feedback circuit. The detection circuit is configured to amplify the weak output voltage with small amplitude of TMR element for operations and filtering. The detection circuit is mainly composed of an instrumentation amplifier with three operational amplifiers, and its REF pin is grounded to keep a very low source impedance. In the detection circuit, a zeroing circuit is designed, in which a precision adjustable resistor is connected in series between two equivalent resistors, and a precision operational amplifier is used as a voltage follower for buffering. The positive input terminal of the precision operational amplifier is connected to the middle pin of the precision adjustable resistor, and its output serves as an output of a zeroing voltage.

The interference suppression circuit includes the element performance error correction circuit and the filtering circuit. The element performance error correction and compensation method based on a signal injection method is used through the decomposition unit according to the distinctive waveform characteristics, to identify the excitation signal from the current detected by TMR element, which is used to calculate the overall gain of the measuring loop of the magnetosensitive sensor, determine the change of the measurement characteristics of the magnetosensitive resistor chip, and generate a regulating current. The filter circuit is configured to filter the possibly coupled high-frequency magnetic field signal to ensure a low-pass characteristic. The filter circuit adopts a second-order Butterworth low-pass filter built based on a precision operational amplifier.

The multi-band feedback circuit is designed according to the multi-band feedback mechanism. According to the difference in the responses, in the sensor circuit, of current signals at different frequencies, multiple dynamic output feedback control circuits (each dynamic output feedback control circuit having a limited frequency band) are designed, the optimization goal of which is to ensure that the transmission characteristics of different frequencies from low frequency to high frequency signals are consistent.

The feedback compensation section consists of the driving circuit, the feedback winding and the output circuit. The amplified output voltage drives the push-pull transistor, and the transistor outputs the feedback current I_c to the compensation coil. At this time, the actual magnetic field on the sensor is the difference between the external magnetic field and the feedback magnetic field. Then, the feedback current is measured according to Ohm's law, the to-be-measured current is obtained through the ratio of the compensation coil turns.

The design scheme of the external structure of the current sensor is as follows: according to the above high-voltage direct current quantum tunneling magnetoresistance current sensing method, the magnetoelectric conversion section is designed as a sensing ring. The voltage insulated is realized by using a special processed ring insulation layer inside the sensing ring, and the power supply and the secondary circuit realize current sensing on the low voltage side.

The disclosure has been described with reference to some embodiments. However, known to those skilled in the art, as defined by the appended claims, other embodiments other than those disclosed above in the disclosure fall equivalently within the scope of the disclosure.

Generally, all terms used in the claims are construed according to their ordinary meanings in technical field, unless otherwise expressly defined therein. All references to “a/said/the [device, component, etc.]” are openly interpreted as at least one instance of the device, the component, etc., unless otherwise expressly stated. The operations of any of the methods disclosed herein need not be perform in the exact order disclosed, unless explicitly stated.

Those skilled in the art will appreciate that the embodiments of the disclosure may be provided as a method, a system or a computer program product. Therefore, the disclosure may take the form of an entirely hardware embodiment, an entirely software embodiment, or an embodiment combining both software and hardware aspects. Furthermore, the disclosure may take the form of a computer program product implemented on one or more computer-readable storage medium (including, but not limited to, disk storage, CD-ROM, optical memory, etc.) containing computer-executable program codes.

The disclosure is described with reference to flowcharts and/or block diagrams of methods, apparatus (systems) and computer program products according to the embodiments of the disclosure. It should be understood that each flow in the flowchart and/or each block in the block diagram, as well as combinations of the flows in the flowchart and/or the blocks in the block diagram, may be implemented by computer program instructions. These computer program instructions may be provided to a processor of a general purpose computer, a special purpose computer, an embedded processor, or other programmable data processing device to generate a machine, such that instructions executed by the processor of the computer or other programmable data processing device generate a device for implementing the functions specified in one or more flows in the flowchart and/or one or more blocks in the block diagram.

These computer program instructions may also be stored in a computer-readable memory capable of directing a computer or other programmable data processing device to operate in a specific manner, such that the instructions stored in the computer-readable memory produce an article of manufacture containing an instruction device for implementing the functions specified in one or more flows in the flowchart and/or one or more blocks in the block diagram.

These computer program instructions may also be loaded onto a computer or other programmable data processing device, such that a series of operating operations is performed on the computer or other programmable device to generate computer-implemented processing, thereby the instructions executed on the computer or other programmable device provide operations for implementing the functions specified in one or more flows in the flowchart and/or one or more blocks in the block diagram.

Finally, it should be noted that the above embodiments are intended only to illustrate and not limit the technical solutions of the disclosure, and while the disclosure has been described in detail with reference to the above embodiments, it should be understood by those of ordinary skill in the art that the specific embodiments of the disclosure may still be modified or equivalently substituted without departing from the spirit and scope of the disclosure. Any such modifications or equivalent substitutions should be encompassed within the scope of protection of the claims of the disclosure.

### INDUSTRIAL APPLICABILITY

In the embodiment of the disclosure, the magnetoelectric conversion unit is configured to: obtain a magnetic field signal of a target current-carrying wire with a to-be-measured current; and convert the magnetic field signal into an electric signal and output the electric signal to the signal processing unit. The magnetoelectric conversion unit adopts a multi-air-gap multi-band closed-loop iron core type structure. The signal processing unit is configured to: amplify the electric signal, and output the amplified signal to the feedback compensation unit. The feedback compensation unit is configured to: adjust a feedback current based on the amplified voltage signal to enable the new magnetoresistance elements to operate at zero magnetic flux; measure a value of the feedback current; and obtain a value of the to-be-measured current based on the value of the feedback current, and output the value of the to-be-measured current. In this way, the multi-air-gap magnetoresistance current sensor for alternating current-direct current adopts a multi-air-gap multi-band closed-loop iron core type structure, thereby improving the measurement performance of the current sensor, solving the problem of high accuracy and wide frequency domain consideration of current measurement for alternating current-direct current, providing technical guidance for the development and application of high-voltage and high-current measurement equipment, and promoting the technology upgrade of high-voltage and high-current measurement equipment.

1. A multi-air-gap magnetoresistance current sensor for alternating current-direct current, comprising:
a magnetoelectric conversion unit, configured to: obtain a magnetic field signal of a target current-carrying wire with a to-be-measured current; and convert the magnetic field signal into a voltage signal and output the voltage signal to a signal processing unit, wherein the magnetoelectric conversion unit comprises an iron core and N new magnetoresistance elements connected in parallel, N air-gap openings are symmetrically arranged on the iron core, and the N new magnetoresistance elements are respectively located at centers of the N air-gap openings, N≥3 and N is a positive integer;
the signal processing unit, configured to: amplify the voltage signal output by the magnetoelectric conversion unit, and output the amplified voltage signal to a feedback compensation unit; and
the feedback compensation unit, configured to: adjust a feedback current based on the amplified voltage signal output by the signal processing unit to enable the new N magnetoresistance elements to operate at zero magnetic flux; measure a value of the feedback current; and obtain a value of the to-be-measured current based on the value of the feedback current, and output the value of the to-be-measured current.

2. The multi-air-gap magnetoresistance current sensor for alternating current-direct current of claim 1, wherein
the iron core is a circular magnetic gathering ring and is uniformly wound with a feedback winding, and the magnetoelectric conversion unit further comprises a power supply circuit which is respectively connected to the N new magnetoresistance elements for power supply; and
when the target current-carrying wire with the to-be-measured current is placed at a center of the iron core, the N new magnetoresistance elements are used for obtaining the magnetic field signal of the target current-carrying wire with the to-be-measured current, converting the magnetic field signal into the voltage signal, and outputting the voltage signal to the signal processing unit.

3. The multi-air-gap magnetoresistance current sensor for alternating current-direct current of claim 2, wherein the operation that the N new magnetoresistance elements are used for obtaining the magnetic field signal of the target current-carrying wire with the to-be-measured current, converting the magnetic field signal into the voltage signal and outputting the voltage signal to the signal processing unit, comprises:
obtaining an input voltage Vᵢ of each of the N new magnetoresistance elements by the following formula:
$${V}_{i} = {K}_{i} {I}_{i} ( {B}_{i n} - {B}_{c} ) ,$$
where Kᵢ is a sensitivity of i-th new magnetoresistance element, Iᵢ is a control current of the i-th new magnetoresistance element, Bᵢₙ is a primary original magnetic field, and B_{c} is a compensation magnetic field generated by the feedback current; and
based on the input voltage of each of the N new magnetoresistance elements, synthesizing and obtaining a combined voltage of the N new magnetoresistance elements according to an equivalent circuit of parallel capacitors, and outputting the combined voltages to the signal processing unit.

4. The multi-air-gap magnetoresistance current sensor for alternating current-direct current of claim 2, wherein the new magnetoresistance element is a tunneling magnetoresistance element.

5. The multi-air-gap magnetoresistance current sensor for alternating current-direct current of claim 2, wherein the signal processing unit comprises:
a detecting circuit, comprising an instrumentation amplifier with three operational amplifiers, wherein the detecting circuit is configured to amplify the voltage signal output by the magnetoelectric conversion unit, and output the amplified voltage signal to the feedback compensation unit;
an interference suppression circuit, used for an element performance error correction circuit and a filtering circuit, wherein the element performance error correction circuit is configured to generate a regulating current based on the voltage signal output by the magnetoelectric conversion unit, and the filtering circuit is configured to filter high-frequency magnetic field signals coupled by the N new magnetoresistance elements to ensure a low-pass characteristic; and
a multi-band feedback circuit, comprising a plurality of dynamic output feedback control circuits for ensuring that transmission characteristics of different frequencies are consistent, each of the plurality of dynamic output feedback control circuits having a limited frequency band.

6. The multi-air-gap magnetoresistance current sensor for alternating current-direct current of claim 2, wherein the feedback compensation unit comprises:
the feedback winding, uniformly wound on the iron core, and configured to pass the feedback current;
a driving circuit, configured to adjust the feedback current output to the feedback winding based on the amplified voltage signal output by the signal processing unit, to enable a compensation magnetic field equal in size and opposite in direction to a primary magnetic field; and
an output circuit, configured to: measure the value of the feedback current, obtain the value of the to-be-measured current based on the value of the feedback current, and output the value of the to-be-measured current.

7. The multi-air-gap magnetoresistance current sensor for alternating current-direct current of claim 6, wherein the output circuit is further configured to:
divide the value of the feedback current by a ratio of coil turns to obtain the value of the to-be-measured current.

8. The multi-air-gap magnetoresistance current sensor for alternating current-direct current of claim 6, wherein the multi-air-gap magnetoresistance current sensor for alternating current-direct current further comprises a ring housing for carrying the iron core wound with the feedback winding and the N new magnetoresistance elements connected in parallel.

9. The multi-air-gap magnetoresistance current sensor for alternating current-direct current of claim 8, wherein the ring housing is voltage insulated by using an insulating layer.

10. A method for measuring a current, comprising: using the multi-air-gap magnetoresistance current sensor for alternating current-direct current of claim 1 to measure a to-be-measured current in a target current-carrying wire, to obtain a value of the to-be-measured current and output the value of the to-be-measured current; wherein the target current-carrying wire is at a center of an iron core of the multi-air-gap magnetoresistance current sensor for alternating current-direct current.
